(19) United States
(12) Patent Application Publication
(10) Pub. No.: US 2002/0142594 A1
(43) Pub. Date: Oct. 3, 2002

(54) Sacrificial films to provide structural integrity to critical dimension structures

(75) Inventors: Terri A. Couteau, Rosanky, TX (US); Michael J. Satterfield, Round Rock, TX (US); Laura A. Pressley, Austin, TX (US); Bruce Pickelsimer, McKinney, TX (US)

Correspondence Address: TIMOTHY M HONEYCUTT ATTORNEY AT LAW, P O BOX 1577, CYPRESS, TX, 77410, US

(73) Assignee: Advanced Micro Devices, Inc.

(21) Appl. No.: 09/819,914

(22) Filed: Mar. 28, 2001

(51) Int. Cl. H01L 21/302; H01L 21/461

(52) U.S. Cl. 438/689

(57) ABSTRACT

Various methods of processing a circuit structure with a protective coating are provided. In one aspect, a method of processing a semiconductor substrate is provided that includes patterning a structure on the substrate and forming a protective coating on the patterned structure while leaving other surfaces on the substrate exposed. The exposed surfaces are cleaned by immersing the substrate in a liquid and subjecting the exposed surfaces to sonic pulses whereby the protective coating increases the strength of the patterned structure to reduce the potential for structural failure induced by the sonic pulses. The protective coating is then removed.

### BACKGROUND OF THE INVENTION

1. Field of the Invention

This invention relates generally to semiconductor processing, and more particularly to methods of cleaning a semiconductor substrate with the aid of a protective coating to defend underlying circuit structures from stresses.

2. Description of the Related Art

During the course of the fabrication of a wafer-based integrated circuit, the wafer and the structures patterned thereon are subjected to a wide variety of processing steps. Many of these fabrication steps involve processes that may induce high mechanical stresses in the circuit structures, such as anneals, etching, ion implantation and sonic cleaning to name just a few. Anneals produce large swings in temperature and pressure, etching and ion implantation involve bombardment by energetic particles, and sonic cleaning entails high frequency vibrations.

As with more macroscopic physical structures, the capability of microscopic circuit structures to withstand mechanical stresses during processing is largely a function of the geometries and bulk moduli of the structures and the magnitude of the induced or applied forces. For a given external stimulus, such as a sonic cleaning pulse or ion beam, a larger structure will be generally less prone to mechanical failure than a relatively smaller structure. It follows then that device scaling has impacted the propensity of circuit structures to fail mechanically during processing.

Closely-spaced critical dimension polysilicon lines represent one example of microcircuit structures that may be prone to mechanical failure due to fabrication stresses. Such structures are typically patterned in huge numbers on a given integrated circuit. Although the widths of these lines may vary widely across a given integrated circuit, the target width is frequently the critical dimension or minimum feature size for the particular process technology. Furthermore, and to satisfy scaling goals, the aspect ratios of these types of structures have steadily climbed above 1.5 in some process flows. When combined with the very low ductility of polysilicon, the patterning with critical dimension widths and high aspect ratios can lead to structures with lower mechanical strength.

In order avoid or lessen the likelihood of mechanical failure of such thin circuit structures during processing, compromises can be made in various processes. For example, implant energies can lowered, sonic cleaning processes can be shortened or conducted at lower acoustic energies, and thermal shocks can be softened. However, such techniques will usually involve trade-offs in device performance or throughput or both. Alternatively, higher levels of structural failure and subsequent rework or scrap may be accepted.

The present invention is directed to overcoming or reducing the effects of one or more of the foregoing disadvantages.

### SUMMARY OF THE INVENTION

In accordance with one aspect of the present invention, a method of processing a semiconductor substrate is provided that includes patterning a structure on the substrate and forming a protective coating on the patterned structure while leaving other surfaces on the substrate exposed. The exposed surfaces are cleaned by immersing the substrate in a liquid and subjecting the exposed surfaces to sonic pulses whereby the protective coating increases the strength of the patterned structure to reduce the potential for structural failure induced by the sonic pulses. The protective coating is then removed.

In accordance with another aspect of the present invention, a method of processing a semiconductor substrate is provided that includes patterning a plurality of polysilicon lines on the substrate and forming a protective coating on the plurality of polysilicon lines while leaving other surfaces on the substrate exposed. The exposed surfaces are cleaned by immersing the substrate in a liquid and subjecting the exposed surfaces to sonic pulses whereby the protective coating increases the strength of the plurality of polysilicon lines to reduce the potential for structural failure induced by the sonic pulses. The protective coating is then removed.

In accordance with another aspect of the present invention, a method of processing a semiconductor substrate is provided that includes patterning a plurality of polysilicon lines on the substrate and forming a protective coating of oxide on the plurality of polysilicon lines while leaving other surfaces on the substrate exposed. The exposed surfaces are cleaned by immersing the substrate in a liquid and subjecting the exposed surfaces to sonic pulses at a frequency of about 950 kHz to 1.5 MHz and a power of about 10 to 300 watts whereby the protective coating of oxide increases the strength of the plurality of polysilicon lines to reduce the potential for structural failure induced by the sonic pulses. The protective coating is then removed.

### BRIEF DESCRIPTION OF THE DRAWINGS

The foregoing and other advantages of the invention will become apparent upon reading the following detailed description and upon reference to the drawings in which:

FIG. 1 is a cross-sectional view of a small portion of a semiconductor substrate upon which a structure is patterned in accordance with the present invention;

FIG. 2 is a cross-sectional view of the substrate of FIG. 1 depicting fabrication of a protective coating on the structure in accordance with the present invention;

FIG. 3 is a cross-sectional view like FIG. 2 depicting masking of a portion of the protecting coating overlying the patterned structure in accordance with the present invention;

FIG. 4 is a cross-sectional view like FIG. 3 depicting etching of an unmasked portion of the substrate in accordance with the present invention;

FIG. 5 is a cross-sectional view like FIG. 4 depicting a strip of the mask in accordance with the present invention;

FIG. 6 is a side view of a sonic cleaning bath in which the substrate may be subjected to sonic cleaning with the protective coating in place in accordance with the present invention;

FIG. 7 is a cross-sectional view like FIG. 5 but depicting an ion implantation of the substrate with the protective coating in place in accordance with the present invention; and

FIG. 8 is a cross-sectional view like FIG. 5 depicting removal of the protective coating in accordance with the present invention.

### DETAILED DESCRIPTION OF SPECIFIC EMBODIMENTS

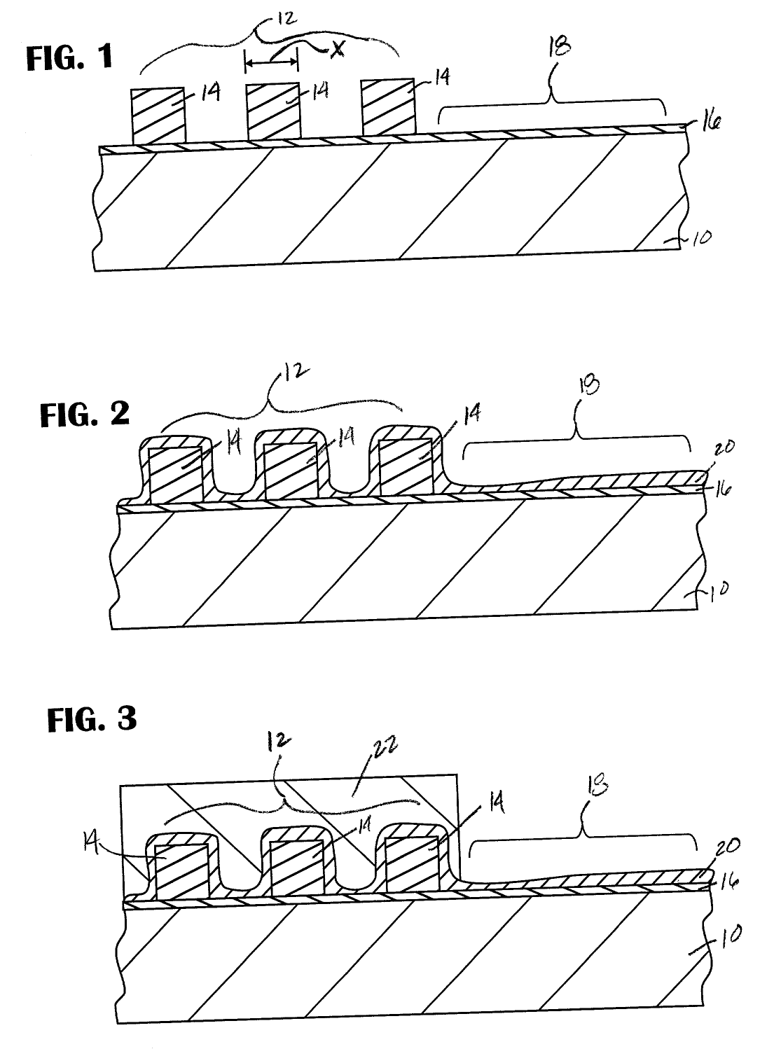

In the drawings described below, reference numerals are generally repeated where identical elements appear in more than one figure. FIG. 1 is a cross-sectional view of a small portion of a semiconductor substrate 10 upon which a structure 12 is patterned. The structure 12 in the illustrated embodiment consists of a plurality of conductor lines 14 patterned with a lateral dimension X which may advantageously correspond to the minimum feature size or critical dimension for the prevailing process technology. Although the patterned structure 12 may consist of any of a large variety of structures patterned on substrates during semiconductor processing, for the present illustration, the structure 12 consists of a plurality of patterned polysilicon lines positioned on an oxide film 16 that may be utilized as a gate dielectric layer if the structures 14 are patterned as transistor gate electrodes. The patterned structure 12 may be fabricated in a myriad of different ways utilizing well known semiconductor fabrication techniques, such as, for example, chemical vapor deposition, physical vapor deposition, electroplating, or other well known deposition techniques. Furthermore, the actual patterning of the structure 12 may be accomplished by well known photolithographic masking and etching techniques, laser ablation or other material removal processes as desired.

As the skilled artisan will appreciate, the fabrication of circuit structures on a semiconductor substrate, such as the substrate 10, involves the performance of a myriad of different processing steps on various portions of the substrate 10. In many cases, it may be desirable to process only certain portions of the substrate 10 without subjecting other small geometry features to the particular processes involved. For example, it may be desirable to perform various processing steps, such as cleansing, ion implantation, or etching processes on a portion 18 of the substrate 10 while not subjecting the patterned structure 12 to the particular process involved. If it is desired to perform an immersion etch of the portion 18 at elevated temperatures, it may be desirable to reduce the thermal shock to the patterned structure 12 associated with the high temperature immersion etch. Similarly, if it is desired to perform an ion implantation into the portion 18, it may be desirable to limit the ionic impacts on the patterned structure 12.

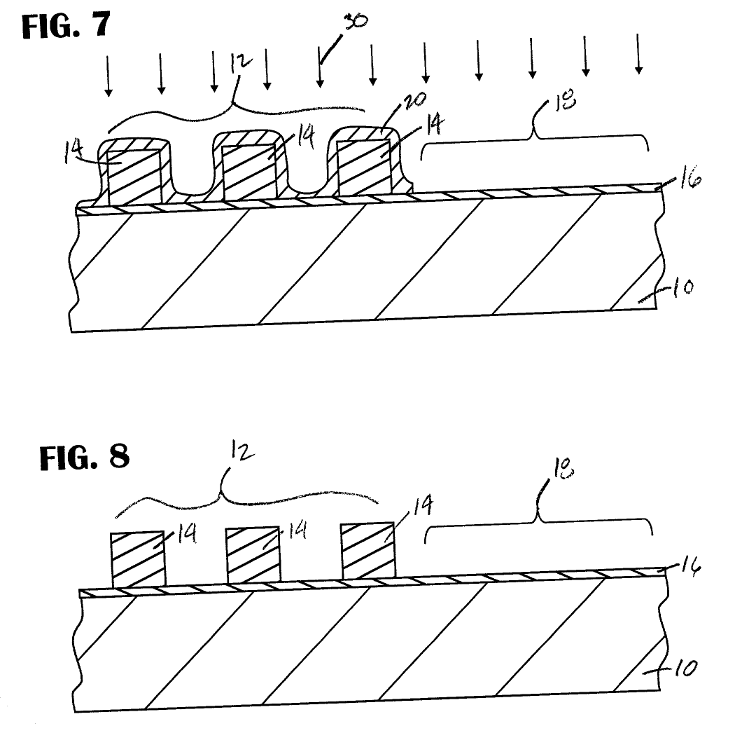

An exemplary method for processing the substrate while providing protection for the patterned structure 12 thereon in accordance with the present invention may be understood by referring now to FIGS. 2, 3, 4, 5, 6, 7 and 8 and initially to FIG. 2. A protective coating 20 is applied to the substrate 10 to cover the patterned structure 12. The film 20 is preferably composed of a dielectric material or a laminate of dielectric materials that may be readily etched away following processing of the portion 18 of the substrate 10. Exemplary materials include, for example, oxide, silicon nitride, silicon oxynitride, laminates of these or the like. The film 20 may be applied using well known CVD techniques with or without plasma enhancement. The desired thickness of the film 20 will be largely dependent upon the minimum device geometry X and subject to design discretion. In an exemplary embodiment, the film 20 may be about 200 to 1700 Å in thickness. Note that the film 20 is blanket deposited over the substrate 10.

Referring now to FIG. 3, a photomask 22 may be applied over the patterned structure 12 using well known lithographic patterning techniques. The purpose of the photo mask 22 is to enable the portion of the protective coating film 20 proximate the portion 18 of the substrate 10 to be etched away while leaving the portion of the film 20 overlying the structure 12 intact. Optionally, the portion of the film 20 coincident with the portion 18 of the substrate 10 may be left in place during subsequent processing as desired.

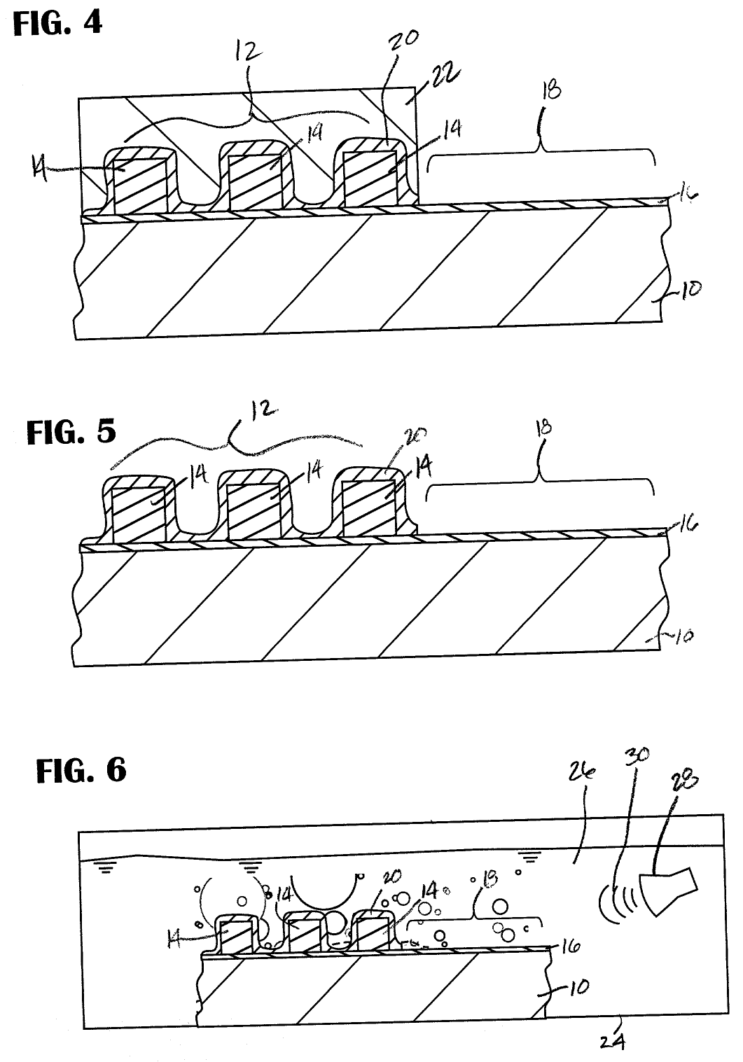

Referring now to FIG. 4, the portion of the protective coating 20 positioned coincident with the portion 18 of the substrate 10 is etched away with the photomask 22 protecting the portion of the film 20 overlying the patterned structure 12. The removal process may be by reactive ion etching, chemical plasma etching, isotropic wet etching, laser ablation or other well known material removal techniques. For example, if the film 20 is composed of oxide, the removal process may be by plasma etching using etch chemistries suitable for etching oxide. Note that if the underlying film 16 is also composed of oxide, care should be exercised during the etch of the film 20 to avoid significant penetration of the underlying substrate 10. If, however, the films 20 and 16 are composed of different materials, then etch selectivity may be easily achieved in circumstances where chemical etching is employed.

Referring now to FIG. 5, the photo mask 22 depicted in FIG. 4 may be stripped by well known ashing and/or solvent stripping techniques. At this point, the substrate 10 may undergo a variety of different processing steps utilized in semiconductor processing. For example, and as shown in FIG. 6, the substrate 10 may be immersed in a cleansing bath 24 containing a cleansing solution 26 and subjected to sonic cleaning. The sonic cleaning may be provided by a source 28 of high frequency sonic pulses 30. In an exemplary embodiment, sonic pulses 36 with a frequency of about 950 kHz to 1.5 MHz, and power of about 10 to 300 Watts are propagated in the cleansing solution 26 at a temperature of about 25° C. The cleansing solution may be ultrapure water, or acid or base solutions consisting of, for example, less than 50% HCl or NH₄OH by volume. Such acid or base solutions may contain up to about 50% by volume H₂O₂. The protective coating 20 provides a barrier to the direct impact of the sonic pulses on the patterned structure 12 and the individual components 14 thereof. In this way, the structural integrity of the patterned structure 12 is increased.

The sonic cleaning process depicted in FIG. 6 represents just one of a myriad of different semiconductor process steps that may be performed on the portion 18 of the substrate with the patterned structure 12 shielded by the protective coating 20. FIG. 7 depicts another of the numerous potential examples. As shown in FIG. 7, the substrate 10 may undergo an ion implantation step. The protective coating 20 will reduce the number and projected range of impurity ions 32 that actually strike the patterned structure 12. The purpose of the protective coating 20 in an ion implantation context is to reduce the amount of crystalline damage in the individual structures 14 at the interface with the underlying layer, in this case the film 16. The skilled artisan will appreciate that crystalline damage at the interface with the film 16 could result in delamination of the structures 14 during subsequent processing. Indeed, following the implantation of the impurity ions 32, the substrate 10 may undergo a cleansing process of the type depicted in FIG. 6. In such circumstances, the protective coating 20 not only diminishes the amount of potential crystalline defects introduced in the lower portions of the patterned structure 12 during the implantation, but also subsequently shields the patterned structure 12 from the full effect of the sonic pulses 30.

Following the performance of the processing steps, e.g., the cleansing, etching or ion implantation depicted in FIG. 6 and 7, the protective coating 20 may be sacrificed or stripped to leave the patterned structure 12 exposed along with the portion 18 of the substrate 10. As with the material removal process depicted in FIG. 4 above, the appropriate stripping process will depend upon the material selected for the protective coating 20. For example, if the coating 20 is composed of silicon nitride, a hot phosphoric acid dip may be appropriate for stripping. Following the stripping process, the semiconductor substrate 10 may undergo further processing appropriate for the particular circuit structures desired.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of processing a semiconductor substrate, comprising:
patterning a structure on the substrate;
forming a protective coating on the patterned structure while leaving other surfaces on the substrate exposed;
cleaning the exposed surfaces by immersing the substrate in a liquid and subjecting the exposed surfaces to sonic pulses;
whereby the protective coating increases the strength of the patterned structure to reduce the potential for structural failure induced by the sonic pulses; and
removing the protective coating.

2. The method of claim 1, wherein the patterning of the structure comprises depositing and selectively etching an polysilicon film.

3. The method of claim 1, wherein the formation of the protective coating comprises growing an oxide film over the patterned structure.

4. The method of claim 1, wherein the formation of the protective coating comprises depositing an oxide film over the patterned structure.

5. The method of claim 1, wherein the formation of the protective coating comprises depositing a silicon nitride film over the patterned structure.

6. The method of claim 1, wherein the liquid comprises a solution of ammonium hydroxide and hydrogen peroxide in water.

7. The method of claim 1, wherein the protective coating is removed by etching.

8. The method of claim 1, comprising implanting the substrate with ions.

9. A method of processing a semiconductor substrate, comprising:
patterning a plurality of polysilicon lines on the substrate;
forming a protective coating on the plurality of polysilicon lines while leaving other surfaces on the substrate exposed;
cleaning the exposed surfaces by immersing the substrate in a liquid and subjecting the exposed surfaces to sonic pulses;
whereby the protective coating increases the strength of the plurality of polysilicon lines to reduce the potential for structural failure induced by the sonic pulses; and
removing the protective coating.

10. The method of claim 9, wherein the formation of the protective coating comprises growing an oxide film over the plurality of polysilicon lines.

11. The method of claim 9, wherein the formation of the protective coating comprises depositing an oxide film over the plurality of polysilicon lines.

12. The method of claim 9, wherein the formation of the protective coating comprises depositing a silicon nitride film over the plurality of polysilicon lines.

13. The method of claim 9, wherein the liquid comprises a solution of ammonium hydroxide and hydrogen peroxide in water.

14. The method of claim 9, wherein the protective coating is removed by etching.

15. The method of claim 9, comprising implanting the substrate with ions.

16. A method of processing a semiconductor substrate, comprising:
patterning a plurality of polysilicon lines on the substrate;
forming a protective coating of oxide on the plurality of polysilicon lines while leaving other surfaces on the substrate exposed;
cleaning the exposed surfaces by immersing the substrate in a liquid and subjecting the exposed surfaces to sonic pulses at a frequency of about 0.950 to 1.5 MHz and a power of about 10 to 300 watts;
whereby the protective coating of oxide increases the strength of the plurality of polysilicon lines to reduce the potential for structural failure induced by the sonic pulses; and
removing the protective coating.

17. The method of claim 16, wherein the formation of the protective coating comprises growing the oxide film over the plurality of polysilicon lines.

18. The method of claim 16, wherein the formation of the protective coating comprises depositing the oxide film over the plurality of polysilicon lines.

19. The method of claim 16, wherein the formation of the protective coating comprises depositing a silicon nitride film over the plurality of polysilicon lines.

20. The method of claim 16, wherein the liquid comprises a solution of ammonium hydroxide and hydrogen peroxide in water.

21. The method of claim 16, wherein the protective coating is removed by etching.

22. The method of claim 16, comprising implanting the substrate with ions.
